(19) United States
(12) Patent Application Publication
(10) Pub. No.: US 2025/0126823 A1
(43) Pub. Date: Apr. 17, 2025

(54) FERROELECTRIC SEMICONDUCTOR THIN FILM AND METHOD OF FORMING THE SAME AND TRANSISTOR AND MEMORY DEVICE AND INTEGRATED CIRCUIT

(71) Applicant: ADRC. CO. KR, Seoul (KR)

(72) Inventors: Jin JANG, Seoul (KR); Jun Hyuk CHEON, Seoul (KR); Taebin Lim, Seoul (KR)

(21) Appl. No.: 18/898,848

(22) Filed: Sep. 27, 2024

(30) Foreign Application Priority Data
Oct. 16, 2023 (KR) 10-2023-0137942
Sep. 2, 2024 (KR) 10-2024-0118685

(51) Int. Cl. H01L 29/66; H01L 21/28; H01L 29/04; H01L 29/51; H01L 29/78; H10B 51/30

(52) U.S. Cl. CPC H10D 30/0415; H10B 51/30; H10D 30/701; H10D 62/405; H10D 64/033; H10D 64/689

(57) ABSTRACT

Disclosed are a ferroelectric semiconductor thin film, a method of forming the ferroelectric semiconductor thin film, a transistor, a memory device and an integrated circuit. The method of forming the ferroelectric semiconductor thin film includes preparing a precursor solution including an indium precursor and a selenium precursor, and performing spray pyrolysis of the precursor solution on a substrate to obtain the ferroelectric semiconductor thin film including a polycrystalline γ-In₂Se₃ layer.

### CROSS-REFERENCE TO RELATED APPLICATIONS

This application claims priority to and the benefit of Korean Patent Application No. 10-2023-0137942 filed at the Korean Intellectual Property Office on Oct. 16, 2023, and Korean Patent Application No. 10-2024-0118685 filed at the Korean Intellectual Property Office on Sep. 2, 2024, the entire contents of which are incorporated herein by reference.

### BACKGROUND OF THE INVENTION

### (a) Field of the Invention

A ferroelectric semiconductor thin film, a method of forming the ferroelectric semiconductor thin film, a transistor, a memory device, and an integrated circuit are disclosed.

### (b) Description of the Related Art

Ferroelectric semiconductors have been studied as next-generation semiconductor materials. Ferroelectric semiconductors are materials that have both ferroelectric characteristics, in which spontaneous polarization is observed, and semiconductor characteristics.

### SUMMARY OF THE INVENTION

One embodiment provides a ferroelectric semiconductor thin film that may be applied to a large area and has excellent electrical characteristics.

Another embodiment provides a method of forming the ferroelectric semiconductor thin film.

Another embodiment provides a transistor including the ferroelectric semiconductor thin film.

Another embodiment provides a memory device including the ferroelectric semiconductor thin film or the transistor.

Another embodiment provides an integrated circuit including the ferroelectric semiconductor thin film, the transistor, or the memory device.

According to one embodiment, a method of forming the ferroelectric semiconductor thin film includes preparing a precursor solution including an indium precursor and a selenium precursor, and performing spray pyrolysis of the precursor solution on a substrate to obtain the ferroelectric semiconductor thin film including a polycrystalline γ-In₂Se₃ layer.

In the step of spray pyrolyzing the precursor solution, a temperature of the substrate may be about 250° C. to about 310° C.

The method may further include annealing in an inert gas atmosphere in the step of spray pyrolysis of the precursor solution or thereafter.

The annealing may be performed at a temperature of about 200° C. to about 500° C.

The step of spray pyrolysis of the precursor solution may be performed multiple times to obtain a plurality of polycrystalline γ-In₂Se₃ layers stacked continuously.

The substrate may be covered with a dielectric layer.

According to another embodiment, a ferroelectric semiconductor thin film formed by the above method and including the polycrystalline γ-In₂Se₃ layer is provided.

Peaks in the X-ray diffraction spectrum of the polycrystalline γ-In₂Se₃ layer may be observed at 2θ=25°, 28°, and 45°, corresponding to crystal planes (110), (006), and (300).

Peaks in the Raman shift spectrum of the polycrystalline γ-In₂Se₂ layer may be observed at 95 cm⁻¹, 145 cm⁻¹, 208 cm⁻¹, and 243 cm⁻¹.

The polycrystalline γ-In₂Se₃ layer may be a two-dimensional material.

The polycrystalline γ-In₂Se₃ layer may have a structure in which multiple monolayers are stacked.

The polycrystalline γ-In₂Se₃ layer may have a plurality of c-axis oriented grains and a grain boundary between the adjacent c-axis oriented grains.

The polycrystalline γ-In₂Se₃ layer may have Se vacancies.

An optical band gap of the polycrystalline γ-In₂Se₃ layer may be about 1.0 eV to about 1.8 eV.

According to another embodiment, an electronic device including the ferroelectric semiconductor thin film is provided.

According to another embodiment, a transistor includes a gate electrode, the ferroelectric semiconductor thin film overlapping the gate electrode, a gate dielectric layer between the gate electrode and the ferroelectric semiconductor thin film, and a source electrode and a drain electrode electrically connected to the ferroelectric semiconductor thin film.

The ferroelectric semiconductor thin film may be patterned to overlap a portion of the gate dielectric layer.

According to another embodiment, a memory device including the transistor is provided.

According to another embodiment, an integrated circuit including the transistor or the memory device is provided.

A ferroelectric semiconductor thin film may be applied to a large area and have excellent electrical characteristics.

### BRIEF DESCRIPTION OF THE DRAWINGS

FIG. 1 is a schematic diagram showing the crystal structure of the polycrystalline γ-In₂Se₃ layer,

FIG. 2 is a cross-sectional view showing an example of a transistor according to an embodiment,

FIG. 3 is a graph showing a depth profile of each atom in the In₂Se₃ layer according to Preparation Example analyzed by XPS,

FIG. 4 shows an XPS spectrum of In3d in the middle region of the In₂Se₃ layer according to Preparation Example,

FIG. 5 shows an XPS spectrum of Se3d in the middle region of the In₂Se₃ layer according to Preparation Example,

FIG. 6 shows an XPS spectrum of O1s in the middle region of the In₂Se₃ layer according to Preparation Example,

FIG. 7 shows an EDS mapping image of indium (In) in the In₂Se₃ layer according to Preparation Example,

FIG. 8 shows an EDS mapping image of selenium (Se) of an In₂Se₃ layer according to Preparation Example,

FIG. 9 shows a top-view SEM image of the In₂Se₃ layer according to Preparation Example,

FIGS. 10 and 11 show SEM images of enlarged areas A and B of FIG. 9,

FIG. 12 shows an AFM image of the In₂Se₃ layer according to Preparation Example,

FIGS. 13A and 13B show an AFM image in which an area A of FIG. 12 is enlarged and a graph showing a surface roughness according to a position obtained from the AFM image, respectively,

FIGS. 14A and 14B show an AFM image in which an area B of FIG. 12 is enlarged and a graph showing a surface roughness according to a position obtained from the AFM image, respectively,

FIGS. 15A and 15B show an AFM image in which an area C of FIG. 12 is enlarged and a graph showing a surface roughness according to a position obtained from the AFM image, respectively,

FIG. 16 shows an XRD spectrum of the In₂Se₃ layer according to Preparation Example,

FIG. 17 shows an XRD spectrum of the In₂Se₃ layer according to the temperature for spray pyrolysis,

FIG. 18 shows an XRD spectrum of the In₂Se₃ layer according to the N₂ annealing temperature,

FIG. 19 shows a Raman shift spectrum of the In₂Se₃ layer according to Preparation Example,

FIG. 20 shows a Raman shift spectrum of the In₂Se₃ layer according to the N₂ annealing temperature,

FIG. 21 shows a SEM image of the In₂Se₃ layer according to Preparation Example,

FIGS. 22A to 22C show Raman spectra in areas A, B and C of FIG. 21,

FIG. 23 shows a TEM image of the In₂Se₃ layer according to Preparation Example,

FIG. 24 shows a high-resolution high-angle annular dark-field scanning electron microscopy (HAADF-STEM) image of the In₂Se₃ layer according to Preparation Example,

FIG. 25 shows a fast Fourier transform (FFT) pattern of areas A and B of FIG. 24,

FIG. 26 shows an FFT pattern extracted from the entire area of FIG. 24,

FIGS. 27 and 28 are graphs showing hysteresis characteristics according to V_{DS} of the thin-film transistor according to Example,

FIG. 29 is a graph showing a change in electrical characteristics according to a channel length of the thin-film transistor according to Example,

FIG. 30 is a graph showing hysteresis characteristics during 10 sweeps of the thin-film transistor according to Example,

FIG. 31 is a graph showing output characteristics of the thin-film transistor according to Example,

FIG. 32 is a graph showing current characteristics of thin-film transistors according to 42 Examples,

FIG. 33 shows a PFM switching spectroscopic loop using a dual-frequency resonance tracking method on the γ-In₂Se₃ layer of the thin-film transistor according to Example,

FIG. 34 is a graph showing the retention characteristics of the current I_{D}S after the write (−40V, 1 s) and erase (erasing, +40V, 1 s) pulses of the thin-film transistor according to Example, and

FIG. 35 is a graph showing durability results for 500 cycles of write/erase of the thin-film transistor according to Example.

### DETAILED DESCRIPTION OF THE EMBODIMENTS

Hereinafter, example embodiments of the present disclosure will be described in detail so that a person skilled in the art would understand the same. This disclosure may, however, be embodied in many different forms and is not construed as limited to the embodiments set forth herein. In the drawings, the thicknesses of layers, films, panels, regions, etc., are exaggerated for clarity. Like reference numerals designate like elements throughout the specification. It should be understood that when an element such as a layer, film, region, or substrate is referred to as being “on” another element, it can be directly on the other element or intervening elements may also be present. In contrast, when an element is referred to as being “directly on” another element, there are no intervening elements present. Hereinafter, “combination” includes a mixture or a stacked structure of two or more. Hereinafter, “metal” includes metals and semi-metals. As used herein, when a definition is not otherwise provided, “substituted” refers to replacement of a hydrogen atom of a compound by a substituent selected from a halogen, a hydroxy group, a nitro group, a cyano group, an amino group, a carbonyl group, a thiol group, an ester group, a carboxyl group or a salt thereof, a sulfonic acid group or a salt thereof, a phosphoric acid group or a salt thereof, a C₁ to C₃₀ alkyl group, a C₂ to C₃₀ alkenyl group, a C₂ to C₃₀ alkynyl group, a C₆ to C₃₀ aryl group, a C₁ to C₃₀ alkoxy group, a C₁ to C₃₀ heteroalkyl group, a C₃ to C₃₀ heterocyclic group, a C₃ to C₃₀ cycloalkyl group, a C₃ to C₁₅ cycloalkenyl group, a C₆ to C₁₅ cycloalkynyl group, a C₃ to C₃₀ heterocycloalkyl group, and any combination thereof. Hereinafter, a ferroelectric semiconductor thin film according to an embodiment will be described.

A ferroelectric semiconductor thin film according to an embodiment includes a polycrystalline γ-In₂Se₃ layer. The polycrystalline γ-In₂Se₃ layer has a non-symmetric crystalline structure and may exhibit strong out-of-plane (OOP) and in-plane (IP) ferroelectricity at room temperature.

The polycrystalline γ-In₂Se₃ layer may be a continuous thin film formed by a solution process to be described later, and unlike conventional In₂Se₃ flakes obtained by mechanical and/or chemical exfoliation of a single crystal In₂Se₃, thickness control may be easy and patterning such as photolithography may be possible.

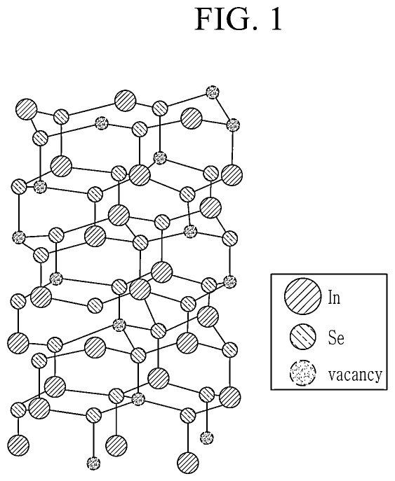

FIG. 1 is a schematic diagram showing the crystal structure of the polycrystalline γ-In₂Se₃ layer.

Referring to FIG. 1, the crystal structure of the polycrystalline γ-In₂Se₃ layer may be a wurtzite structure in which indium (In) and selenium (Se) are helically arranged. In and Se may be substantially uniformly distributed throughout the thin film, and the crystal structure may have a plurality of Se vacancies that Se sites are empty. The polycrystalline γ-In₂Se₃ layer may have an oxygen-free structure that does not include oxygen. Such Se vacancies and oxygen-free structures may provide improved semiconductor characteristics for the polycrystalline γ-In₂Se₃ layer. The optical band gap of the polycrystalline γ-In₂Se₃ layer may show semiconductor characteristics, for example, they may be about 1.0 to about 1.8 eV, and within the range, about 1.1 to about 1.7 eV or about 1.2 to about 1.6 eV.

The polycrystalline γ-In₂Se₃ layer may have a plurality of c-axis oriented crystalline grains and grain boundaries between the adjacent crystalline grains. Unlike grains that are randomly oriented without a direction or formed by aggregation in a cluster form, the plurality of c-axis-oriented crystalline grains may form a uniform and dense thin film, and thus a ferroelectric semiconductor thin film including the polycrystalline γ-In₂Se₃ layer may have a high film density. The grain boundaries may be in different directions, and a polycrystalline structure may be confirmed therefrom. The crystalline grains and the grain boundaries may be uniformly distributed throughout the polycrystalline γ-In₂Se₃ layer.

The polycrystalline γ-In₂Se₃ layer may be a two-dimensional material. Since the two-dimensional material may grow only in a horizontal direction (e.g., xy direction), the two-dimensional material may be formed into a monolayer extending in a horizontal direction, and a plurality of monolayers may be formed to be stacked in a vertical direction (e.g., z direction). Accordingly, the polycrystalline γ-In₂Se₃ layer having a desired thickness may be obtained by adjusting the number of times the monolayers are stacked. Each monolayer may have an atomic-level thickness, for example, about 1 Å to about 10 nm thick, and by controlling the number of times the monolayers are stacked, the polycrystalline γ-In₂Se₃ layer with a thickness of about 1 nm to about 500 nm may be obtained.

The chemical composition of the polycrystalline γ-In₂Se₃ layer may be analyzed by X-ray photoelectron spectroscopy (XPS), and the substantial atomic ratio of In and Se obtained by XPS analysis may be about 1:1.20 to about 1:1.30. The existence of the above-described Se vacancies may be confirmed from the atomic ratio.

The crystal structure of the polycrystalline γ-In₂Se₃ layer may be analyzed by X-ray diffraction (XRD) and Raman spectrum.

The main peaks of the XRD spectrum of the polycrystalline γ-In₂Se₃ layer may be observed at 2θ=25°, 28°, and 45°, and the XRD main peaks at 2θ=25°, 28°, and 45° may correspond to crystal planes (110), (006), and (300), respectively, confirming that it is a γ-phase In₂Se₃. Each XRD main peak may appear in narrow width and high intensity, which may indicate the high crystallinity of the γ-In₂Se₃ layer.

The main peaks of the Raman spectrum of the polycrystalline γ-In₂Se₃ layer may be observed at 95 cm⁻¹, 145 cm⁻¹, 208 cm⁻¹, and 243 cm⁻¹, and the main peaks at 95 cm⁻¹, 145 cm⁻¹, 208 cm⁻¹, and 243 cm⁻¹ may correspond to the E_{g}¹, A_{1g}¹, E_{g}² and A_{1g}² phonon modes of the γ-phase In₂Se₃ layer, respectively.

Such a polycrystalline γ-In₂Se₃ layer may simultaneously have both ferroelectric characteristics where spontaneous polarization occurs and semiconductor characteristics, and may be formed as a relatively uniform and stable large-area thin film by the method described below.

A ferroelectric semiconductor thin film including the polycrystalline γ-In₂Se₃ layer may be formed by a solution process, for example, spray pyrolysis of a precursor solution including an In precursor and a Se precursor. Hereinafter, an embodiment of the method of forming the above-described ferroelectric semiconductor thin film will be described.

A ferroelectric semiconductor thin film according to an embodiment may include preparing a precursor solution including an In precursor and a Se precursor, and performing spray pyrolysis of the precursor solution on a substrate to obtain the ferroelectric semiconductor thin film including a polycrystalline γ-In₂Se₃ layer.

The precursor solution may include the In precursor, the Se precursor, and a solvent.

The In precursor may be, for example, indium salt, indium hydroxide, indium alkoxide, a hydrate thereof, or a combination thereof, and may be, for example, indium chloride, indium chloride hydrate, indium bromide, indium bromide hydrate, indium iodide, indium iodide hydrate, indium fluoride, indium fluoride hydrate, indium acetate, indium acetate dihydrate, indium acetylacetonate, indium acetylacetonate hydrate, indium nitrate, indium nitrate hydrate, indium nitride, indium nitride hydrate, or a combination thereof, but is not limited thereto.

The Se precursor may be, for example, a selenium salt, selenium hydroxide, selenium alkoxide, a hydrate thereof, or a combination thereof, for example, selenium chloride, selenium chloride hydrate, a substituted or unsubstituted selenourea, selenite, or a combination thereof, but is not limited thereto.

The In precursor and the Se precursor may be included in an amount of about 0.1 to about 50 wt %, respectively, based on a total weight of the precursor solution, within the range of about 1 to about 40 wt %, or about 5 to about 30 wt %. The In precursor and the Se precursor may be determined in a desired atomic ratio in consideration of electrical characteristics, and In and Se in the precursor solution may be included in a mole ratio of, for example, about 2:3.

The solvent is not particularly limited as long as it may dissolve or disperse the In precursor and the Se precursor, for example, methanol, ethanol, propanol, isopropanol, 2-methoxyethanol, 2-ethoxyethanol, 2-propoxyethanol, methyl cellosolve, ethyl cellosolve, diethylene glycol methyl ether, diethylene glycol methyl ether, diethylene glycol methyl ether, toluene, xylene, hexane, heptane, ethyl acetate, butyl acetate, diethylene glycol dimethyl ether, methyl methoxy propionic acid, ethyloxy propionic acid, ethyl lactic acid, propylene glycol methyl ether, propylene glycol propyl ether, propylene glycol propyl ether, methyl cellosolve ether, methyl cellosolve acetate, ethyl cellosolve acetate, diethylene glycol methyl acetate, acetone, methyl isobutyl ketone, cyclohexanone, dimethylformamide (DMF), N-methyl-2-pyrrolidone, γ-butyrolactone, diethyl glycol dimethyl ether, diethylene glycol dimethyl methyl ether, diethyl glycol dimethyl methyl ether, diethyl glycol dimethylene ethyl ether, diethyl glycol dimethylfuran, acetylacetone, acetonitrile, or a combination thereof, but is not limited thereto.

The precursor solution may be stirred at a predetermined temperature for uniform blending, for example, at a temperature of about 30° C. to about 150° C., and then further filtering may be performed.

The substrate may be a glass plate, a polymer substrate, or a silicon wafer. The polymer substrate may include, for example, polyethylene terephthalate, polyethylene naphthalate, polycarbonate, polyacrylate, polymethyl methacrylate, polyimide, polyamide, polyamidimide, a copolymer thereof, or a combination thereof, but is not limited thereto. For example, the substrate may be a glass plate, a polymer substrate, or a silicon wafer covered with a dielectric layer, and the dielectric layer may be, for example, silicon oxide, silicon nitride, silicon oxynitride, aluminum oxide, aluminum nitride, aluminum oxynitride, or a combination thereof.

The spray pyrolysis of the precursor solution on the substrate may be performed by placing the substrate on a heating device such as a hot plate or a heating substrate holder. A high temperature of about 250° C. or higher may be supplied to the substrate by the heating device. The spray pyrolysis of the precursor solution may be performed at, for example, about 250° C. to about 310° C., and within the range, at about 260° C. to about 310° C., or about 270° C. to about 300° C. Here, the temperature may be a surface temperature of the substrate or a surface temperature of the heating device. The polycrystalline γ-In₂Se₃ layer having the above-described structure may be formed by performing spray pyrolysis at a temperature within the above range.

The spray pyrolysis of the precursor solution may be performed under an inert gas atmosphere (including an N₂ atmosphere). The spray time and interval may be various in consideration of the concentration of the precursor solution, a thickness to be formed, and the like, for example, it may be performed for 1 second to 100 seconds at once or several times at predetermined intervals.

The method may further include annealing in an inert gas atmosphere (including an N₂ atmosphere) after spray pyrolysis of the precursor solution or thereafter. The inert gas atmosphere may be, for example, N₂, He, Ar, or a combination thereof. The crystallinity of the polycrystalline γ-In₂Se₃ layer may be increased by annealing. Annealing may be performed at a temperature of about 200° C. or higher, for example about 200° C. to about 500° C., about 200° C. to about 450° C., about 200° C. to about 400° C., about 250° C. to about 500° C., about 250° C. to about 450° C., about 300° C. to about 500° C., about 300° C. to about 450° C., or about 300° C. to about 400° C.

The precursor solution may be spray-pyrolyzed to form the polycrystalline γ-In₂Se₃ layer having the above-described structure. The polycrystalline γ-In₂Se₃ layer may be formed as a monolayer of a two-dimensional structure, and multiple polycrystalline γ-In₂Se₃ layers may be formed continuously by performing such spray pyrolysis multiple times. The number of a plurality of stacked polycrystalline γ-In₂Se₃ layers may be determined according to a desired thickness, for example, 2 to 300 layers.

Unlike conventional In₂Se₃ flakes obtained by mechanical and/or chemical exfoliation of single-crystal In₂Se₃, the ferroelectric semiconductor thin film including polycrystalline γ-In₂Se₃ layers obtained by spray pyrolysis may be effectively applied as a large-area thin film since they may control the thickness and be formed uniformly from front to back as well as patterning such as photolithography. In addition, the ferroelectric semiconductor thin film, including polycrystalline γ-In₂Se₃ layers obtained by spray pyrolysis, may show good electrical characteristics due to the crystal structure and high crystallinity, while reducing manufacturing costs and simplifying the process.

The above-described ferroelectric semiconductor thin film may be applied to various electronic devices including semiconductors. For example, the above-described ferroelectric semiconductor thin film may be applied to a transistor.

Hereinafter, a transistor according to an embodiment will be described with reference to the drawings.

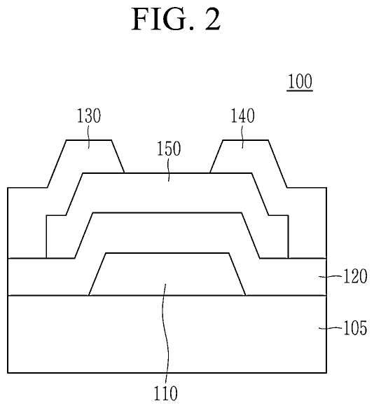

FIG. 2 is a cross-sectional view illustrating an example of a transistor according to an embodiment.

Referring to FIG. 2, a transistor 100 according to an embodiment includes a gate electrode 110, a gate dielectric layer 120, a source electrode 130, a drain electrode 140, and a ferroelectric semiconductor thin film 150.

A substrate 105 may be a support substrate supporting the transistor 100, for example, a glass plate, a polymer substrate, or a silicon wafer. The polymer substrate may include, for example, polyethylene terephthalate, polyethylene naphthalate, polycarbonate, polyacrylate, polymethylmethacrylate, polyimide, polyamide, polyamide, a copolymer thereof, or a combination thereof, but is not limited thereto.

The gate electrode 110 is electrically connected to a gate line that transmits a gate signal. The gate electrode 110 may be made of, for example, gold (Au), copper (Cu), nickel (Ni), aluminum (Al), molybdenum (Mo), chromium (Cr), tantalum (Ta), titanium (Ti), an alloy thereof, or a combination thereof, but is not limited thereto. However, when the substrate 105 is a silicon wafer, the gate electrode 110 may be a doped region of the silicon wafer. The gate electrode 110 may be one layer or two or more layers.

The gate dielectric layer 120 may be positioned on the gate electrode 110 and may cover a whole surface of the substrate 105. The gate dielectric layer 120 may include an organic material, an inorganic material, and/or an organic-inorganic material, for example, an oxide, a nitride, and/or an oxynitride, such as but not limited to silicon oxide, silicon nitride, silicon oxynitride, aluminum oxide, aluminum nitride, aluminum oxynitride, or a combination thereof. The gate dielectric layer 120 may be one layer or two or more layers.

The source electrode 130 and the drain electrode 140 are positioned on the gate dielectric layer 120. The source electrode 130 and the drain electrode 140 face each other around the ferroelectric semiconductor thin film 150 and are electrically connected to the ferroelectric semiconductor thin film 150. The source electrode 130 may be electrically connected to a data line (not shown) that transmits a data signal, and the drain electrode 140 may be island-shaped. The source electrode 130 and the drain electrode 140 may be made of, for example, a metal such as gold (Au), copper (Cu), nickel (Ni), aluminum (Al), molybdenum (Mo), chromium (Cr), tantalum (Ta), titanium (Ti), or an alloy thereof, or a conductive oxide such as indium tin oxide (ITO) and indium zinc oxide (IZO), but are not limited thereto.

The ferroelectric semiconductor thin film 150 may be positioned to overlap the gate electrode 110 with the gate dielectric layer 120 interposed therebetween, and may be positioned between the source electrode 130 and the drain electrode 140. The ferroelectric semiconductor thin film 150 may be patterned (e.g., island-shaped) to overlap a part of the gate dielectric layer 120 (e.g., a position overlapping the gate electrode 110).

As described above, the ferroelectric semiconductor thin film 150 includes the polycrystalline γ-In₂Se₃ layer formed by spray pyrolysis and may have both ferroelectric and semiconductor characteristics. The ferroelectric semiconductor thin film 150 may be an active layer and may include a channel region of the transistor 100. Since the ferroelectric semiconductor thin film 150 has both ferroelectric and semiconductor characteristics as described above, it may exhibit switchable spontaneous polarization characteristics, and thus may be effectively applied to a channel of a transistor.

The above-described transistor may be applied to various electronic devices, for example, to a memory device. The above-described transistor or memory device may be applied to an integrated circuit.

The integrated circuit may be included in various electronic devices. Such electronic devices may include, for example, mobile devices, computers, laptops, tablet PCs, smart watches, sensors, digital cameras, e-books, network devices, vehicle navigation, Internet of Things (IoT), Internet of Everything (IoE), drones, door locks, safes, ATMs, security devices, medical devices, or automotive electronic components, but are not limited thereto.

For example, electronic devices may include a memory unit, an arithmetic logic unit, and a control unit, which may be electrically connected to each other. For example, the memory unit, the arithmetic logic device, and the control unit may be implemented as a chip, and for example, monolithically integrated on a substrate to be implemented as a chip. The memory unit, the arithmetic logic device, and the control unit may each independently include a transistor and/or a memory element. The electronic device may be connected to one or more input/output devices.

Hereinafter, the embodiments are illustrated in more detail with reference to examples. However, these examples are exemplary, and the present scope is not limited thereto.

### PREPARATION EXAMPLE

### (1) Preparation of Precursor Solution

Ethanol (≥99.9%) and 2-methoxyethanol (99.8%) are mixed in a volume ratio of 7:3 to prepare 20 ml of a mixed solvent. Subsequently, under a nitrogen environment, indium chloride (InCl₃, 99.999%, Sigma Aldrich) and 1,1-dimethyl-2-selenourea ((CH₃)₂NC(Se)NH₂, 97%, Sigma Aldrich) are added to the mixed solvent at molar concentrations of 0.04M and 0.06M, respectively, and stirred at 120° C. for 5 minutes to obtain a transparent solution. Subsequently, the transparent solution is filtered at 85° C. for 10 minutes using a Buchi rotary evaporator to obtain about 2 mL of a yellow precursor solution.

### (2) Preparation of In₂Se₃ Layer

Spray pyrolysis is performed by a cyclone atomizing method using a lab spray coater (SRC-2200, Nano Force). First, Ar/O₂ plasma treatment and UV/O₃ treatment are performed four times on a 15 cm×15 cm glass substrate with SiO₂ at 100° C. for 300 seconds to reduce interfacial conditions and obtain a hydrophilic surface. Then, the glass substrate with SiO₂ is placed on the heating substrate holder and heated to 275° C. The spray nozzle is then placed over the glass substrate so that the distance between the glass substrate and the spray nozzle is about 12 cm, and the nozzle is moved at a speed of 7 cm/s to perform spray pyrolysis. Spray pyrolysis is performed at a rate of approximately 0.3 mL/min with 80 seconds of a spray time per cycle for the entire substrate to form an In₂Se₃ monolayer. The spray pyrolysis described above is then further repeated 9 times in a row (a total of 10 cycles) to form an In₂Se₃ layer. Subsequently, the In₂Se₃ layer is annealed in an N₂ furnace at 270° C. for 1 hour.

### Evaluation I

The chemical composition of the In₂Se₃ layer according to Preparation Example is analyzed.

The chemical composition is analyzed using X-ray photoelectron spectroscopy (XPS, Thermofisher, Nexsa) and energy dispersion X-ray spectroscopy (EDS). XPS evaluates the depth profile of In, Se, O, and Si in the In₂Se₃ layer, and EDS performs elemental mapping in the In₂Se₃ layer.

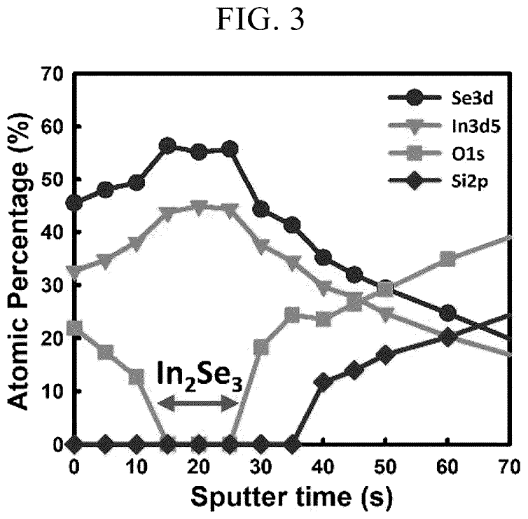

The results are shown in FIGS. 3 to 8.

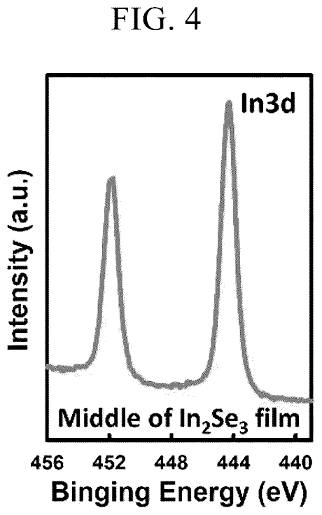

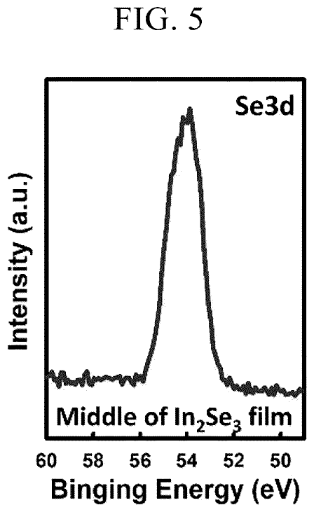

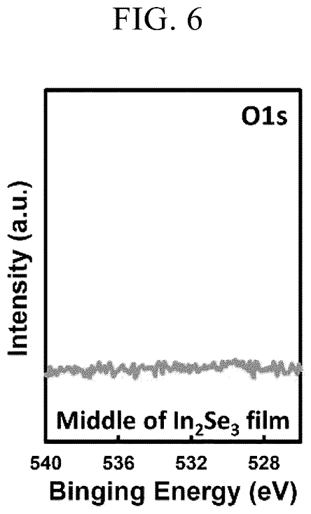

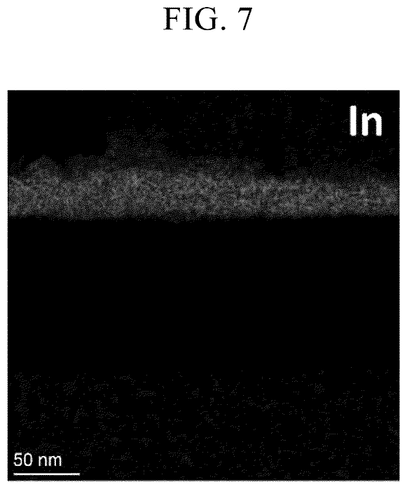

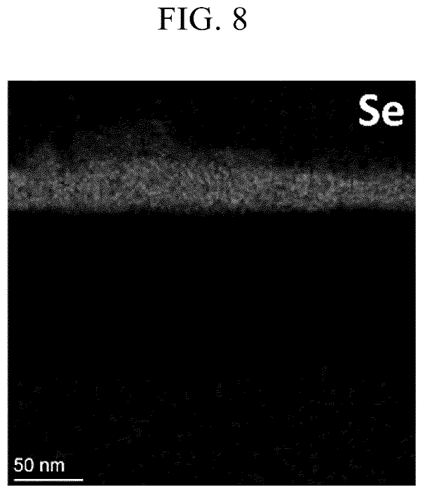

FIG. 3 is a graph showing a depth profile of each atom in the In₂Se₃ layer according to Preparation Example analyzed by XPS, FIG. 4 shows an XPS spectrum of In3d in the middle region of the In₂Se₃ layer according to Preparation Example, FIG. 5 shows an XPS spectrum of Se3d in the middle region of the In₂Se₃ layer according to Preparation Example, FIG. 6 shows an XPS spectrum of O1s in the middle region of the In₂Se₃ layer according to Preparation Example, FIG. 7 shows an EDS mapping image of indium (In) in the In₂Se₃ layer according to Preparation Example, and FIG. 8 shows an EDS mapping image of selenium (Se) of an In₂Se₃ layer according to Preparation Example.

Referring to FIG. 3, it may be confirmed that the atomic ratio of In and Se in the In₂Se₃ layer according to Preparation Example is about 1:1.26, and from this, it is confirmed that the In₂Se₃ layer according to Preparation Example has Se vacancies.

In addition, referring to FIGS. 3 to 6, clear peaks of In and Se in the In₂Se₃ layer according to Preparation Example may be confirmed, and from this, the existence of In and Se and their chemical bonds may be confirmed. Further, it may be seen that there is no peak of oxygen (O) in the In₂Se₃ layer according to Preparation Example, and from this, the In₂Se₃ layer according to Preparation Example may be confirmed as an oxygen-free layer.

Further, referring to FIGS. 7 and 8, from EDS mapping, the distribution of In (blue) and Se (pink) in the In₂Se₃ layer according to Preparation Example may be confirmed.

### Evaluation II

The surface morphology of the In₂Se₃ layer according to Preparation Example is evaluated.

The surface morphology is evaluated using a scanning electron microscope (SEM, FEI Apreo S Hivac) and an atomic force microscope (AFM, Park Systems NX-10).

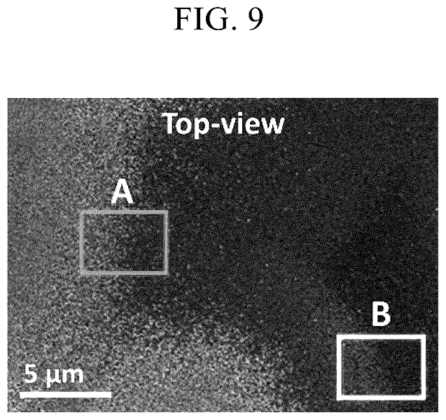

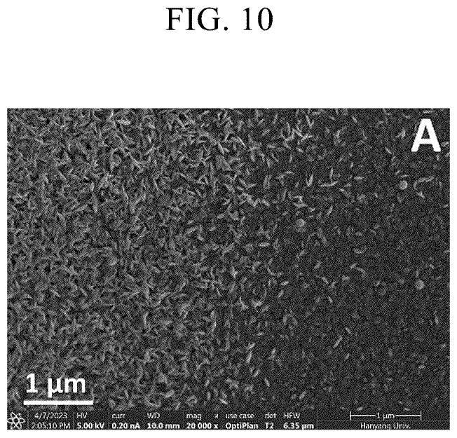

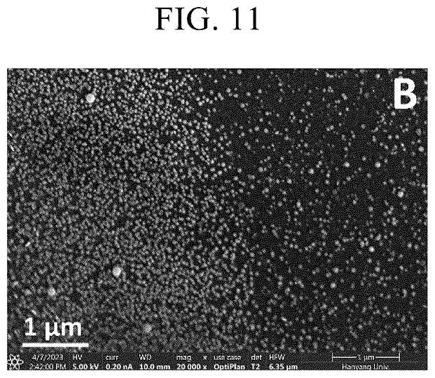

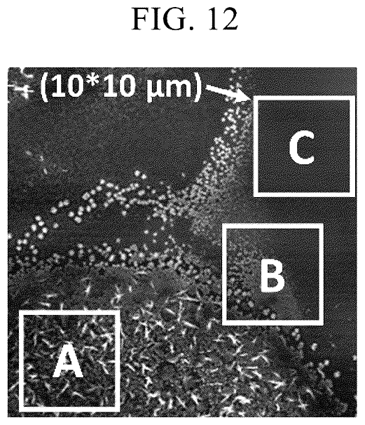

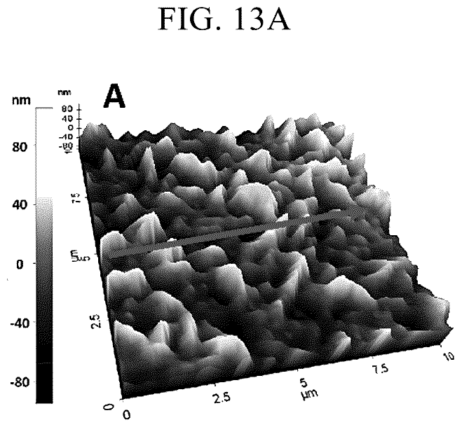

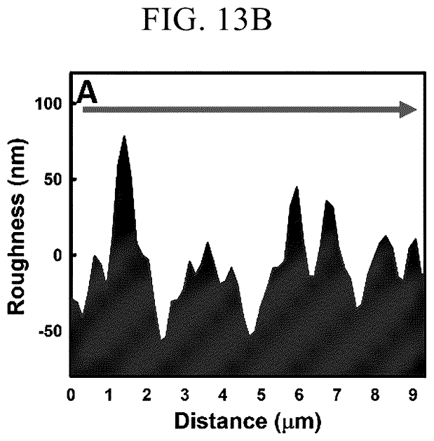

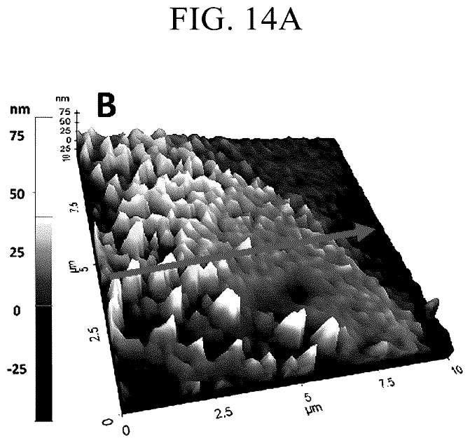

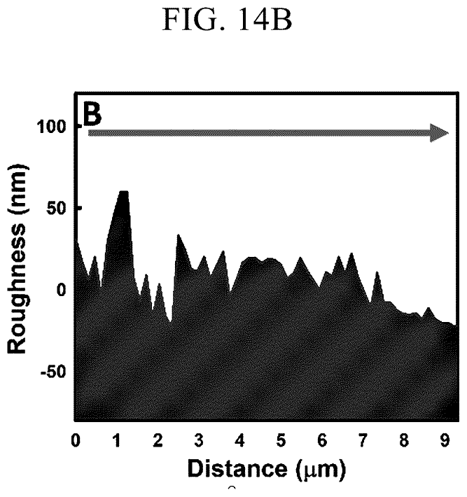

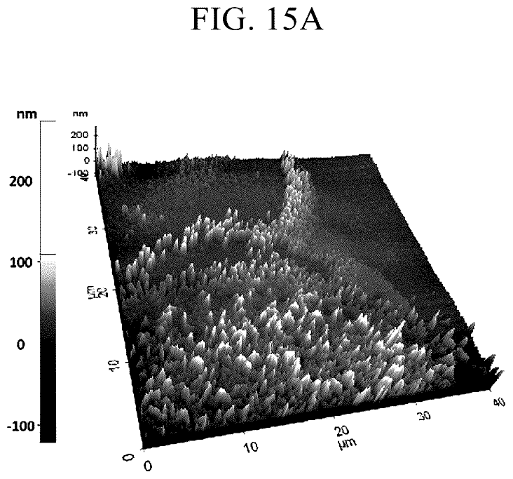

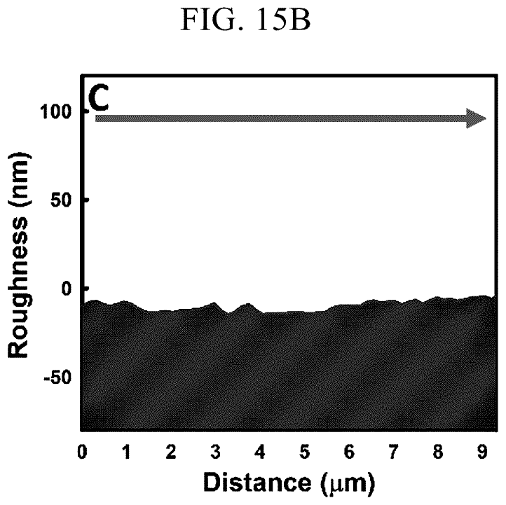

FIG. 9 shows a top-view SEM image of the In₂Se₃ layer according to Preparation Example, FIGS. 10 and 11 show SEM images of enlarged areas A and B of FIG. 9, FIG. 12 shows an AFM image of the In₂Se₃ according to Preparation Example, FIGS. 13A and 13B show an AFM image in which an area A of FIG. 12 is enlarged and a graph showing a surface roughness according to a position obtained from the AFM image, respectively, FIGS. 14A and 14B show an AFM image in which an area B of FIG. 12 is enlarged and a graph showing a surface roughness according to a position obtained from the AFM image, respectively, and FIGS. 15A and 15B show an AFM image in which an area C of FIG. 12 is enlarged and a graph showing a surface roughness according to a position obtained from the AFM image, respectively.

Referring to FIGS. 9 to 11, the In₂Se₃ layer according to Preparation Example shows two distinct surface morphologies, specifically, area A shows a crystal structure randomly formed in the shape of rods less than or equal to about 200 nm in length, and area B shows a smooth area consisting of continuous small islands less than or equal to about 80 nm in diameter.

Referring to FIGS. 12 and 13A to 15B, it may be seen that the In₂Se₃ layer according to Preparation Example shows different surface morphologies depending on positions, and areas A and B show relatively large surface roughness, while area C shows substantially flat surface. The average roughness Rₐ in areas A, B, and C was evaluated to be about 23.9 nm, about 15.2 nm, and about 6.3 nm, respectively.

### Evaluation III

The crystal structure of the In₂Se₃ layer according to Preparation Example is evaluated.

The crystal structure is evaluated by X-ray diffraction (XRD, SmartLab Rigaku), Raman shift spectrum (Thermo Fisher Scientific DXR-3xi), and transmission electron microscopy (TEM, FEI Double Cs & Monochromatic TEM).

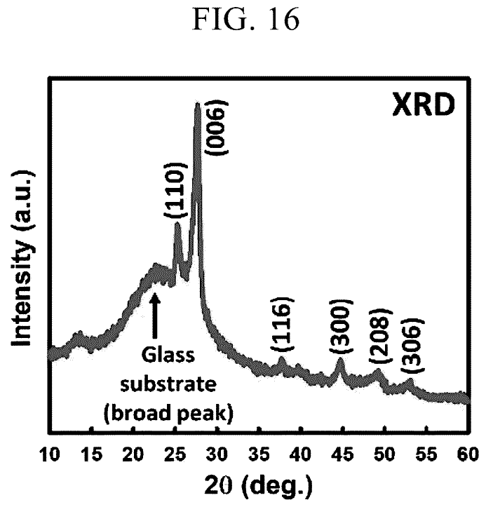

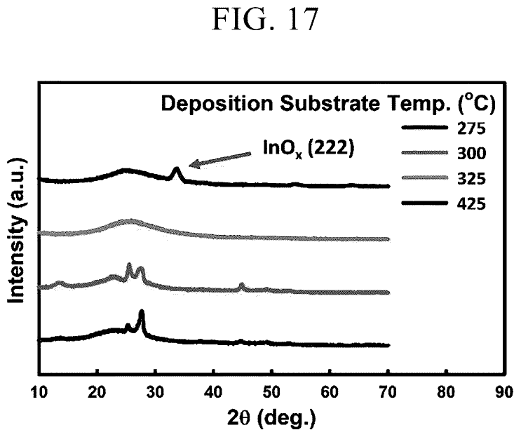

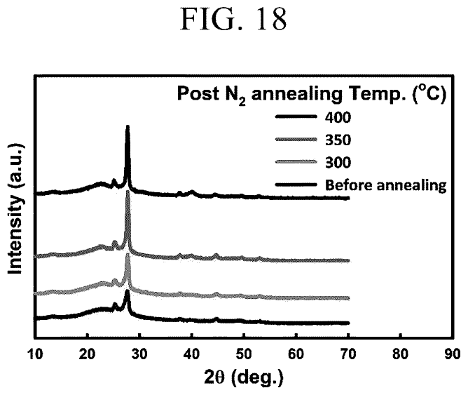

FIG. 16 shows an XRD spectrum of the In₂Se₃ layer according to Preparation Example, FIG. 17 shows an XRD spectrum of the In₂Se₃ layer according to the temperature of spray pyrolysis, and FIG. 18 shows an XRD spectrum of the In₂Se₃ layer according to the N₂ annealing temperature.

Referring to FIG. 16, the XRD main peaks of the In₂Se₃ layer according to Preparation Example are observed at 2θ=25°, 28°, and 45°, which correspond to the crystal plane (110), (006), and (300), respectively, and it may be confirmed that the In₂Se₃ layer is a γ-phase In₂Se₃ layer. In addition, it is expected to have high crystallinity from the observation of sharp peaks with a narrow width at 2θ=25° and 28°, which correspond to the crystal planes (110) and (006), respectively.

Referring to FIG. 17, it may be confirmed that the temperature of spray pyrolysis plays an important role in the crystal structure of the γ-In₂Se₃ layer. Specifically, the γ-In₂Se₃ layer is clearly formed when the temperature of spray pyrolysis is 275° C. and 300° C., whereas the peak is not observed when the temperature of spray pyrolysis is 325° C. and 425° C. In addition, it may be seen that an InOₓ peak is observed when the temperature of spray pyrolysis is 425° C.

Referring to FIG. 18, it may be seen that the crystallinity of the γ-In₂Se₃ layer is affected by N₂ annealing. Specifically, it may be confirmed that the In₂Se₃ layer with N₂ annealing has higher crystallinity than the In₂Se₃ layer without N₂ annealing, and the higher the temperature of N₂ annealing, the higher the crystallinity.

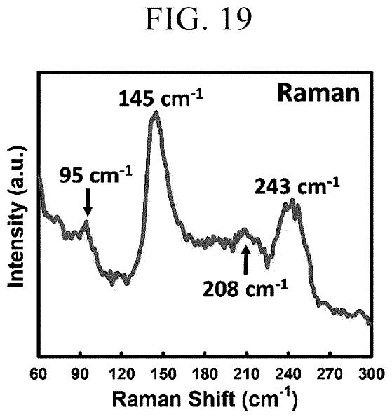

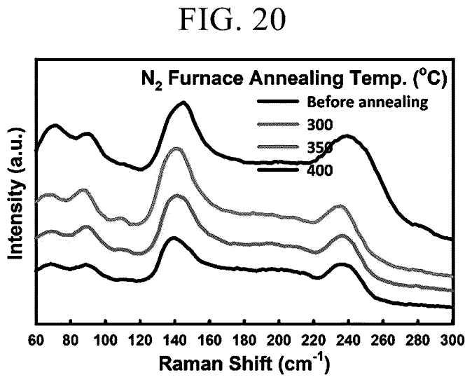

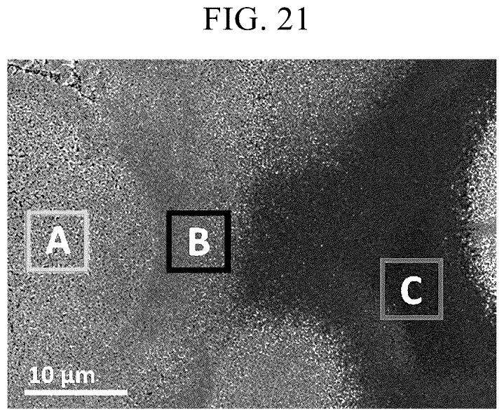

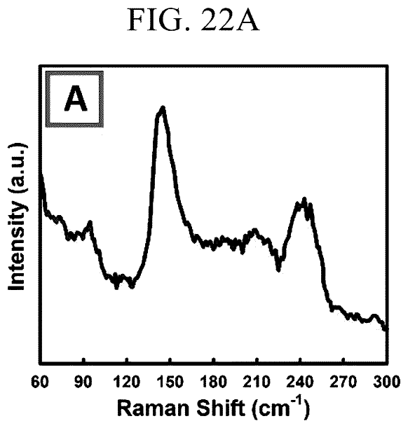

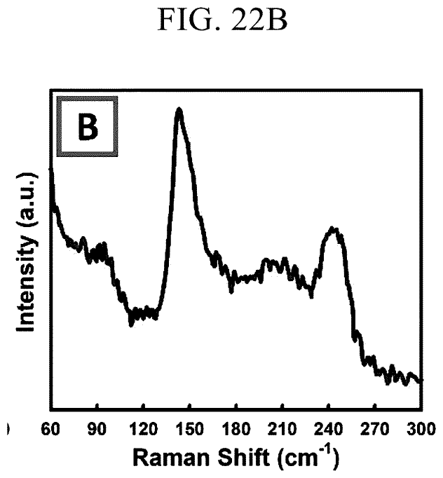

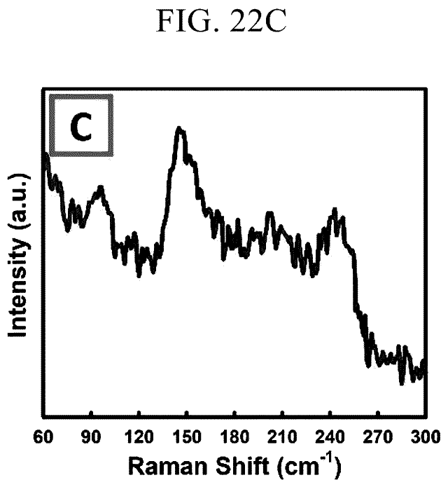

FIG. 19 shows a Raman shift spectrum of the In₂Se₃ layer according to Preparation Example, FIG. 20 shows a Raman shift spectrum of the In₂Se₃ layer according to the N₂ annealing temperature, FIG. 21 shows a SEM image of the In₂Se₃ layer according to Preparation Example, and FIGS. 22A to 22C show Raman spectra in areas A, B, and C, respectively, of FIG. 21.

Referring to FIG. 19, Raman spectra of the In₂Se₃ layer according to Preparation Example are observed at 95 cm⁻¹, 145 cm⁻¹, 208 cm⁻¹, and 243 cm⁻¹, which may correspond to E_{g}¹, A_{1g}¹, E_{g}² and A_{1g}² phonon modes of γ-phase In₂Se₃ layer, respectively. From this, it may be confirmed that the In₂Se₃ layer according to Preparation Example is a γ-phase In₂Se₃ layer.

Referring to FIG. 20, it may be confirmed that the crystallinity of the γ-In₂Se₃ layer is affected by N₂ annealing. Specifically, the In₂Se₃ layer with N₂ annealing shows higher crystallinity than the In₂Se₃ layer without N₂ annealing, and the higher the temperature of N₂ annealing, the higher the crystallinity.

Referring to FIGS. 21 and 22a to 22c, it may be seen that main peaks (95 cm⁻¹, 145 cm⁻¹, 208 cm⁻¹, and 243 cm⁻¹) are observed in the In₂Se₃ layer according to Preparation Example, and from this, it is confirmed that the In₂Se₃ layer according to Preparation Example is a γ-In₂Se₃ layer as a whole.

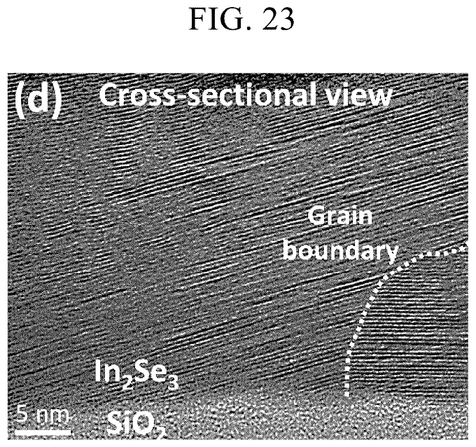

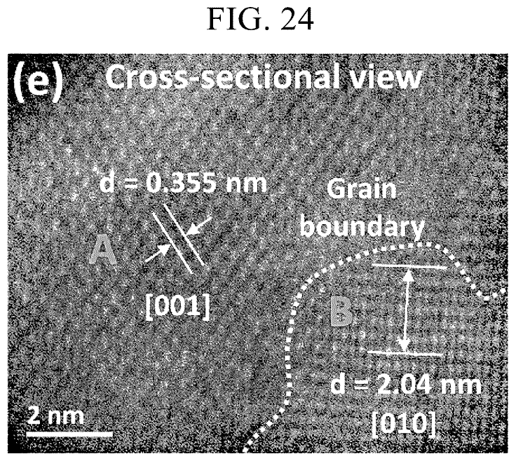

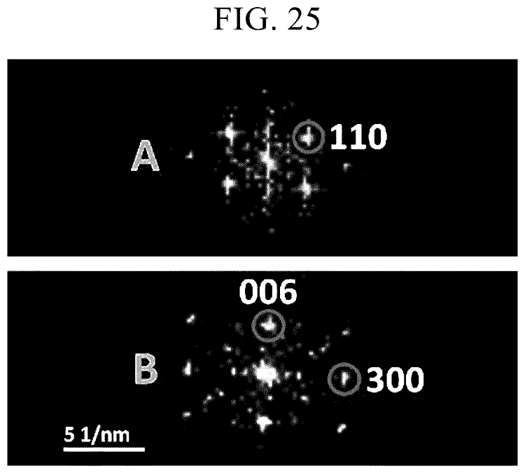

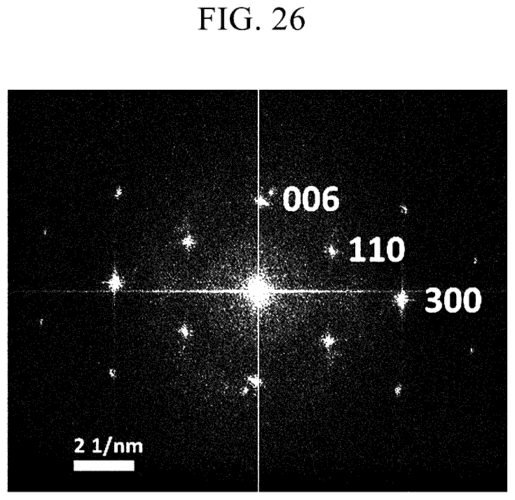

FIG. 23 shows a transmission electron microscope (TEM) image of the In₂Se₃ layer according to Preparation Example, FIG. 24 shows a high-resolution, high-angle annular dark-field scanning electron microscopy (HAADF-STEM) image of the In₂Se₃ layer according to Preparation Example, FIG. 25 shows a fast Fourier transform (FFT) pattern of areas A and B of FIG. 24, and FIG. 26 shows an FFT pattern extracted from the entire area of FIG. 24.

Referring to FIG. 23, it may be seen that the In₂Se₃ layer according to Preparation Example has grain boundaries between crystalline grains arranged in c-axis and adjacent grains oriented in different directions. From this, it may be confirmed that the In₂Se₃ layer according to Preparation Example is a polycrystalline In₂Se₃ layer.

Referring to FIGS. 24 and 25, a spot corresponding to the crystal plane (110) was observed in the FFT pattern extracted from area A, and spots corresponding to the crystal planes (006) and (300) were observed in the FFT pattern extracted from area B. From this, it may be seen that areas A and B have different crystal orientations. In addition, d-spacing {110}=0.355 nm in area A and the 2.04 nm gap between helical periods of the wurtzite structure in area B may support the FFT pattern.

Referring to FIG. 26, spots corresponding to the crystal plane (110), (006), and (300) may be observed in the In₂Se₃ layer according to Preparation Example, which is consistent with the above-described XRD spectrum.

### Evaluation IV

The optical band gap of the In₂Se₃ layer according to Preparation Example is evaluated.

The optical band gap is extracted from a Tauc plot.

As a result, the optical band gap of the In₂Se₃ layer according to Preparation Example is found to be about 1.50 eV. From this, it may be confirmed that the In₂Se₃ layer according to Preparation Example has semiconductor characteristics.

### Manufacturing a Thin-Film Transistor

### EXAMPLE

Molybdenum (Mo) is deposited on a 15 cm×15 cm substrate (glass substrate) by DC sputtering and then patterned to form a 120-nm thick gate electrode. Subsequently, SiNₓ/SiO₂ (60 nm/90 nm) is deposited on the gate electrode by the PECVD method at a temperature of 420° C. to form a gate dielectric layer. Then, the substrate is placed on the heating substrate holder and heated to 275° C. Subsequently, the spray nozzle is placed over the substrate so that the distance between the substrate and the spray nozzle is about 12 cm, and the nozzle is moved at a speed of 7 cm/s to perform spray pyrolysis. Spray pyrolysis is performed at a rate of about 0.3 mL/min, and the spray time per cycle is 80 seconds over the entire substrate to form an In₂Se₃ monolayer. The aforementioned spray pyrolysis is then further repeated nine times continually (a total of 10 cycles) to form an In₂Se₃ layer, followed by annealing at 270° C. for 1 hour in an N₂ furnace to form a polycrystalline γ-In₂Se₃ layer with a thickness of 40 nm. Subsequently, the polycrystalline γ-In₂Se₃ layer is etched with Mo wet etchant for 15 seconds and rinsed with deionized water to form a ferroelectric semiconductor thin film including the patterned polycrystalline γ-In₂Se₃ layer. Then, Mo is deposited on the ferroelectric semiconductor thin film and the gate dielectric layer by DC sputtering and patterned to form a 150-nm-thick source electrode and drain electrode, manufacturing a thin-film transistor (TFT, channel width: 20 μm, channel length: 5 μm). The TFT is annealed in a vacuum oven (4 hours, 250° C.) and an N₂ furnace (1 hour, 270° C.), respectively.

### Evaluation V

Electrical characteristics of the TFT according to Example are evaluated.

Electrical characteristics are evaluated using a semiconductor parameter analyzer (Agilent 4156C).

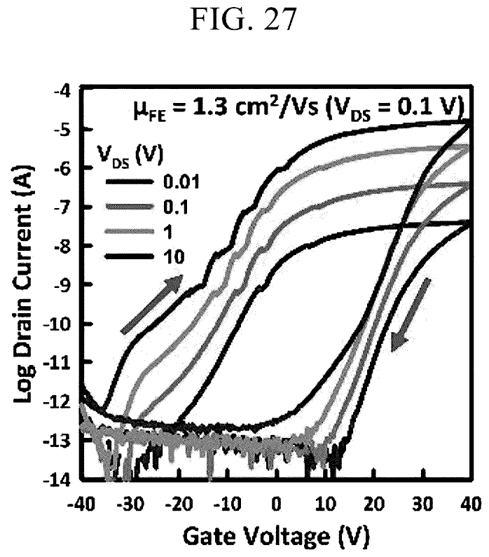

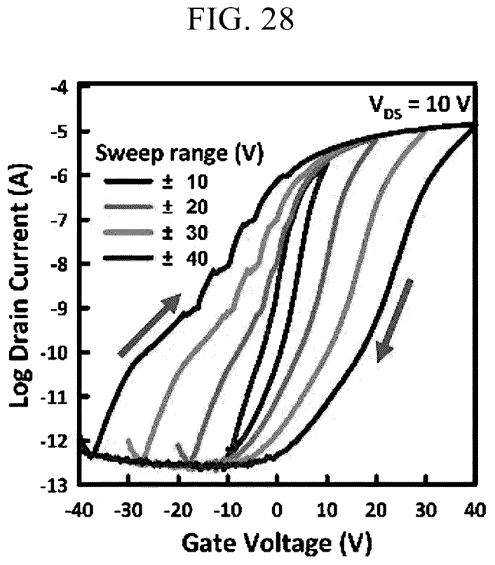

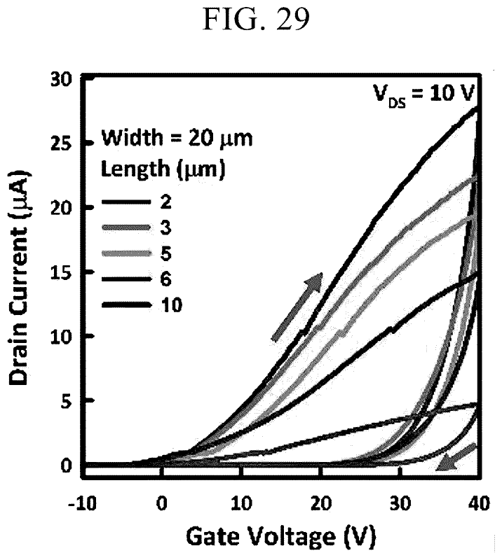

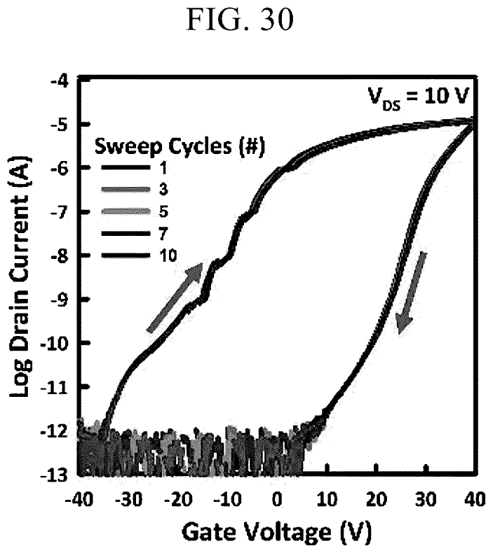

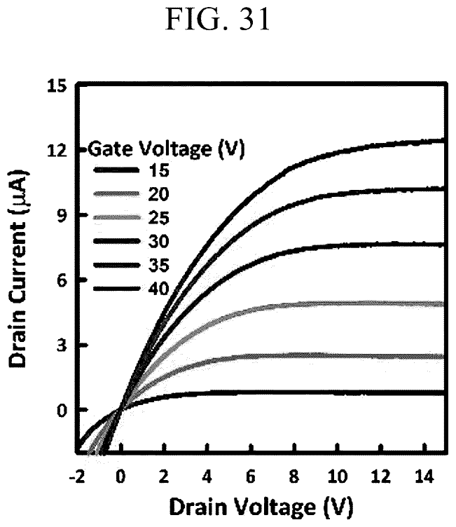

FIGS. 27 and 28 are graphs showing hysteresis characteristics according to V_{DS} of the TFT according to Example, FIG. 29 is a graph showing a change in electrical characteristics according to a channel length of the TFT according to Example, FIG. 30 is a graph showing hysteresis characteristics during 10 sweeps of the TFT according to Example, and FIG. 31 is a graph showing output characteristics of the TFT according to Example.

Referring to FIG. 27, in the TFT according to Example, when the V_{DS} is changed in the range of 0.01 to 10V, hysteresis and low off-currents (<10⁻¹² A) may be observed in all voltage ranges in a clockwise direction.

The field-effect mobility extracted from the I_{DS} measured during the forward sweep is found to be about 1.3 cm²/Vs (at V_{DS}=0.1V).

Referring to FIG. 28, it may be confirmed that the hysteresis range increases significantly when the V_{DS} changes in the range of ±10V to ±40V by expanding the sweep range, which is consistent with the typical characteristics of a ferroelectric-semiconductor field effect transistor (FeS-FET).

Referring to FIG. 29, when the channel width of the TFT according to Example is fixed to 20 μm and the channel length is changed to 2 μm to 10 μm, the on-current increases as the channel length decreases.

Referring to FIG. 30, it is confirmed that the TFT according to Example exhibits substantially the same transfer characteristics during 10 sweeps, thereby confirming the high reliability of the TFT.

Referring to FIG. 31, the TFT according to Example shows good output characteristics, and good ohmic contact between the source/drain electrode and the ferroelectric semiconductor thin film may be confirmed.

From these electrical characteristics, it may be expected that the TFT according to Example may be effectively applied to a large-area device.

### Evaluation VI

Uniformity of electrical characteristics of TFTs according to Example in a large area is evaluated.

Uniformity of electrical characteristics in a large area is evaluated from the current characteristics (I_{DS}) of 42 TFTs manufactured according to Example on a 15 cm×15 cm substrate (glass substrate), sweeping gate voltages in the forward direction with V_{GS}=−40V to +40V and V_{DS}=10V, and immediately sweeping in the reverse direction.

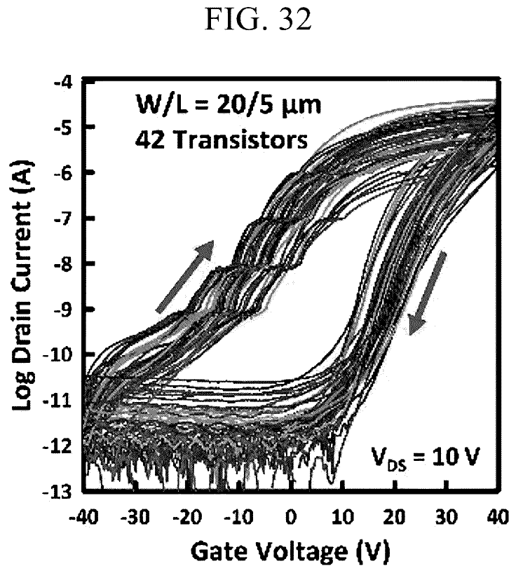

FIG. 32 is a graph showing current characteristics of TFTs according to 42 Examples.

Referring to FIG. 32, substantially the same transfer curves are identified in 42 TFTs according to Example, and from this, it may be confirmed that TFTs with sufficiently uniform electrical characteristics in a large area may be implemented.

### Evaluation VII

Ferroelectric characteristics of the γ-In₂Se₃ layer of the TFT according to Example are evaluated.

Ferroelectric characteristics are identified from the presence of switchable spontaneous polarization induced by external electric fields via piezoresponse force microscopy (PFM).

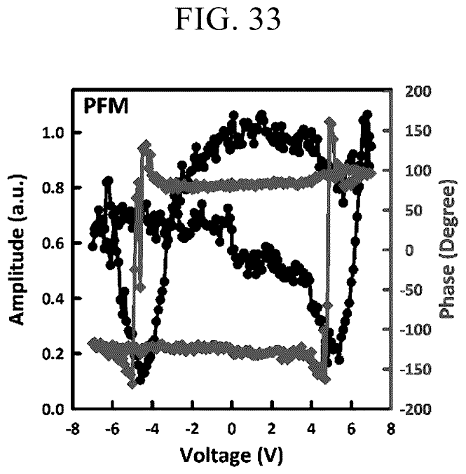

FIG. 33 shows a PFM switching spectroscopic loop using a dual-frequency resonance tracking method on the γ-In₂Se₃ layer of the TFT according to Example.

Referring to FIG. 33, the PFM amplitude and phase signals are measured by sweeping the voltage on the γ-In₂Se₃ layer of the TFT according to Example and the switching possibility of polarization in the γ-In₂Se₃ layer, that is, ferroelectricity, may be confirmed from the difference of 180 degrees between the butterfly shape of the amplitude loop and the phase loop. Based on the minimum points of the amplitude hysteresis loop, it may be confirmed that the positive and negative forcing voltages are +4.8 V and −4.4 V, respectively.

### Evaluation VIII

Nonvolatile memory characteristics of the TFT according to Example are evaluated.

Non-volatile memory characteristics are evaluated by generating voltage pulses using a pulse generator unit connected to a semiconductor parameter analyzer (Agilent 51501B).

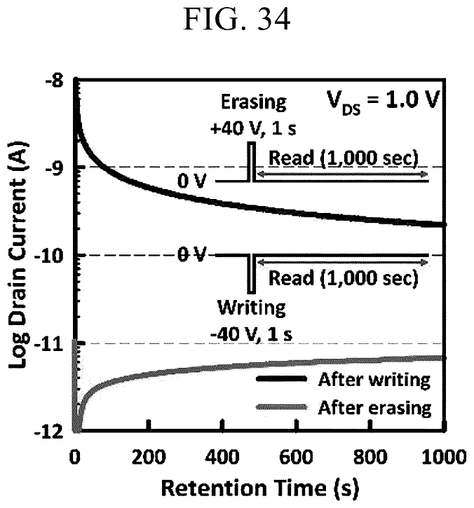

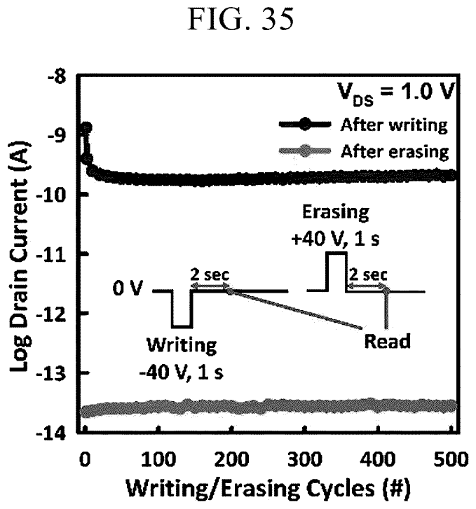

FIG. 34 is a graph showing the retention characteristics of the current IDs after the write (writing, −40V, 1 s) and erase (erasing, +40V, 1 s) pulses of the TFT according to Example, and FIG. 35 is a graph showing durability results for 500 cycles of write/erase of the TFT according to Example.

Referring to FIG. 34, the TFT according to Example maintains the difference in the current I_{DS} after write/erase even after 1000 seconds, and thus it may be confirmed that the TFT has good memory characteristics.

Referring to FIG. 35, it may be confirmed that the TFT according to Example has a current ratio of 10³ or more for a write/erase 500 cycle, and thus has good durability.

While this invention has been described in connection with what is presently considered to be practical exemplary embodiments, it is to be understood that the invention is not limited to the disclosed embodiments, but it is also intended to cover various modifications and equivalent arrangements included within the spirit and scope of the appended claims.

What is claimed is:

1. A method of forming a ferroelectric semiconductor thin film comprising:
preparing a precursor solution including an indium precursor and a selenium precursor, and
performing spray pyrolysis of the precursor solution on a substrate to obtain the ferroelectric semiconductor thin film including a polycrystalline γ-In₂Se₃ layer.

2. The method of claim 1, wherein a temperature of the substrate in the performing of spray pyrolysis of the precursor solution is about 250° C. to about 310° C.

3. The method of claim 1, further comprising:
annealing under an inert gas atmosphere in the performing of spray pyrolysis of the precursor solution or thereafter.

4. The method of claim 3, wherein the annealing is performed at a temperature of about 200° C. to about 500° C.

5. The method of claim 1, wherein the spray pyrolysis of the precursor solution is performed multiple times to obtain a plurality of polycrystalline γ-In₂Se₃ layers stacked continuously.

6. The method of claim 1, wherein the substrate is covered with a dielectric layer.

7. A ferroelectric semiconductor thin film formed by the method according to claim 1, the ferroelectric semiconductor thin film comprising the polycrystalline γ-In₂Se₃ layer.

8. The ferroelectric semiconductor thin film of claim 7, wherein peaks in the X-ray diffraction spectrum of the polycrystalline γ-In₂Se₃ layer are observed at 2θ=25°, 28°, and 45°, corresponding to crystal planes (110), (006), and (300).

9. The ferroelectric semiconductor thin film of claim 7, wherein peaks in the Raman shift spectrum of the polycrystalline γ-In₂Se₃ layer are observed at 95 cm⁻¹, 145 cm⁻¹, 208 cm⁻¹, and 243 cm⁻¹.

10. The ferroelectric semiconductor thin film of claim 7, wherein the polycrystalline γ-In₂Se₃ layer is a two-dimensional material.

11. The ferroelectric semiconductor thin film of claim 10, wherein the polycrystalline γ-In₂Se₃ layer has a structure in which multiple monolayers are stacked.

12. The ferroelectric semiconductor thin film of claim 7, wherein the polycrystalline γ-In₂Se₃ layer has c-axis-oriented grains and a grain boundary between the adjacent c-axis-oriented grains.

13. The ferroelectric semiconductor thin film of claim 7, wherein the polycrystalline γ-In₂Se₃ layer has Se vacancies.

14. The ferroelectric semiconductor thin film of claim 7, wherein an optical band gap of the polycrystalline γ-In₂Se₃ layer is about 1.0 eV to about 1.8 eV.

15. An electronic device comprising the ferroelectric semiconductor thin film according to claim 7.

16. A transistor comprising:
a gate electrode,
the ferroelectric semiconductor thin film according to claim 7, the ferroelectric semiconductor thin film overlapping the gate electrode,
a gate dielectric layer between the gate electrode and the ferroelectric semiconductor thin film, and
a source electrode and a drain electrode electrically connected to the ferroelectric semiconductor thin film.

17. The transistor of claim 16, wherein the ferroelectric semiconductor thin film is patterned to overlap a portion of the gate dielectric layer.

18. A memory device comprising the transistor of claim 16.

19. An integrated circuit comprising the transistor of claim 16.

20. An integrated circuit comprising the memory device of claim 18.
